(19) United States
(12) Patent Application Publication
(10) Pub. No.: US 2009/0083975 A1
(43) Pub. Date: Apr. 2, 2009

(54) Method of interconnecting layers of a printed circuit board

(75) Inventors: Eung-Suek Lee, Ansan-si (KR); Young-Jin Kim, Seoul (KR); Seung-Hyun Baik, Seoul (KR); Jae-Boong Cho, Yongin-si (KR); Young-Seok Oh, Suwon-si (KR); Dae-Woo Suh, Seoul (KR); Je-Gwang Yoo, Yongin-si (KR); Jee-Soo Mok, Yongin-si (KR); Chang-Sup Ryu, Yongin-si (KR)

Correspondence Address: STAAS & HALSEY LLP, SUITE 700, 1201 NEW YORK AVENUE, N.W., WASHINGTON, DC, 20005, US

(73) Assignees: SAMSUNG ELECTRO-MECHANICS CO., LTD., Suwon (KR); SUNGKYUNKWAN UNIVERSITY FOUNDATION FOR CORPORATE COLLABORATION, Suwon-si (KR)

(21) Appl. No.: 12/078,949

(22) Filed: Apr. 8, 2008

(30) Foreign Application Priority Data
Sep. 28, 2007 (KR) 10-2007-0097651

(51) Int. Cl. H05K 3/36

(52) U.S. Cl. 29/830

(57) ABSTRACT

A method of interconnecting layers of a printed circuit board is disclosed. The method includes: forming at least one bump on a first metal layer using a conductive paste containing carbon nanotubes, stacking an insulation layer on the first metal layer such that the bumps penetrate the insulation layer, and stacking a second metal layer on the insulation layer such that the second metal layer is electrically connected with the first metal layer by the bump.

### CROSS-REFERENCE TO RELATED APPLICATIONS

This application claims the benefit of Korean Patent Application No. 10-2007-0097651 filed with the Korean Intellectual Property Office on Sep. 28, 2007, the disclosure of which is incorporated herein by reference in its entirety.

### BACKGROUND

1. Technical Field

The present invention relates to a method of interconnecting layers of a printed circuit board.

2. Description of the Related Art

In step with the development of electro-components, there is a need for improving the performance of HDI (high density interconnection) boards having fine pitch wiring.

This may involve interconnecting different layers of circuit patterns and increasing the degree of freedom in design.

According to the related art, a method of manufacturing a printed circuit board includes forming a plating layer by drilling, chemical plating, and electroplating, and then forming circuit layers. However, such method of manufacturing a printed circuit board does not satisfy the demands for low cost and reduction of lead-time. As such, there is a need for a new process to resolve these problems.

Conductive pastes have been widely used to solve these problems. However, the specific resistances of the conductive pastes are greater than the copper plating, the bonding powers of the conductive pastes are weaker than copper plating, and the polymers within the conductive pastes do not allow adequate thermal conduction.

### SUMMARY

An aspect of the invention is to provide a method of interconnecting layers of a printed circuit board, which uses conductive paste including carbon nanotubes as a filler or as bumps.

One aspect of the invention provides a method of interconnecting layers of a printed circuit board that includes: forming at least one bump on a first metal layer using a conductive paste containing carbon nanotubes; stacking an insulation layer on the first metal layer, such that the bumps penetrate the insulation layer; and stacking a second metal layer on the insulation layer, such that the second metal layer is electrically connected with the first metal layer by the bump. In certain cases, the conductive paste may further contain metal particles and binders.

The first metal layer may advantageously be a circuit pattern formed on a surface of an insulation core layer.

In certain embodiments, the method may further include removing portions of the first and second metal layers to form at least one circuit pattern, after the operation of stacking the second metal layer.

Another aspect of the invention provides a method of interconnecting layers of a printed circuit board that includes: forming at least one through-hole in an insulation layer; forming at least one via by filling a conductive paste containing carbon nanotubes in the through-hole; and stacking a board unit, on which a circuit pattern is formed, on either side of the insulation layer, such that each board unit is electrically connected to each other by the via.

Here, the conductive paste may further contain metal particles and binders.

### BRIEF DESCRIPTION OF THE DRAWINGS

FIG. 1 is a flowchart for a method of interconnecting layers of a printed circuit board according to a first disclosed embodiment of the invention.

FIG. 2, FIG. 3, FIG. 4, FIG. 5, and FIG. 6 are cross-sectional views representing processes for a method of interconnecting layers of a printed circuit board according to a first disclosed embodiment of the invention.

FIG. 7 is a flowchart for a method of interconnecting layers of a printed circuit board according to a second disclosed embodiment of the invention.

FIG. 8, FIG. 9, FIG. 10, FIG. 11, and FIG. 12 are cross-sectional views representing processes for a method of interconnecting layers of a printed circuit board according to a second disclosed embodiment of the invention.

FIG. 13 is a flowchart for a method of interconnecting layers of a printed circuit board according to a third disclosed embodiment of the invention.

FIG. 14, FIG. 15, FIG. 16, and FIG. 17 are cross-sectional views representing processes for a method of interconnecting layers of a printed circuit board according to a third disclosed embodiment of the invention.

### DETAILED DESCRIPTION

The method of interconnecting layers of a printed circuit board according to certain embodiments of the invention will be described below in more detail with reference to the accompanying drawings, in which those elements that are the same or are in correspondence are rendered the same reference numeral regardless of the figure number, and redundant explanations are omitted.

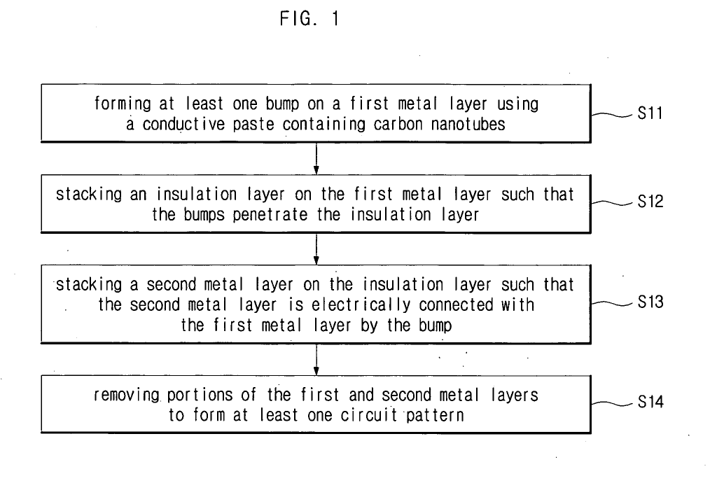

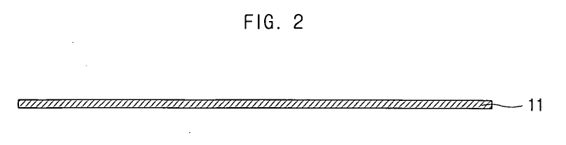

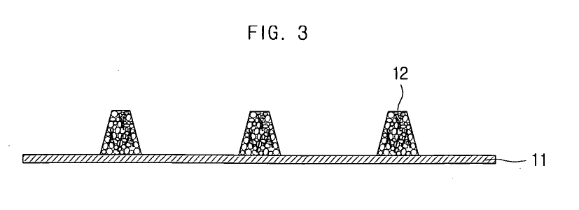

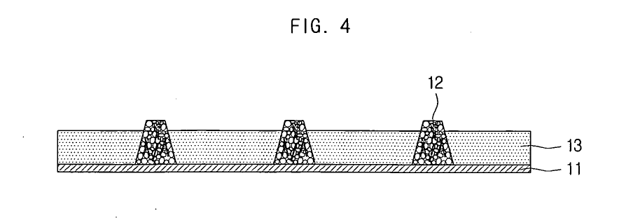

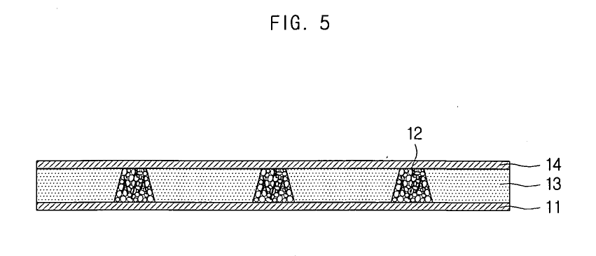

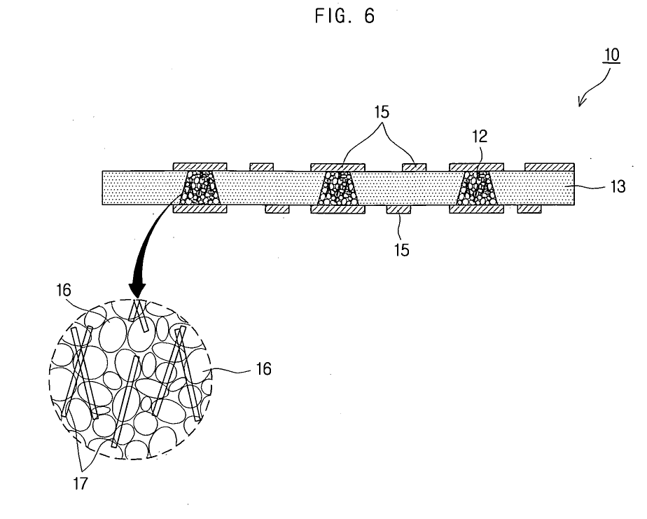

FIG. 1 is a flowchart for a method of interconnecting layers of a printed circuit board according to a first disclosed embodiment of the invention, and FIG. 2 to FIG. 6 are cross-sectional views representing processes for a method of interconnecting layers of a printed circuit board according to a first disclosed embodiment of the invention. In FIGS. 2 to 6 are illustrated a printed circuit board 10, a first metal layer 11, bumps 12, an insulation layer 13, a second metal layer 14, circuit patterns 15, metal particles 16, and carbon nanotubes 17.

Operation S11 of FIG. 1 may be to form at least one bump on a first metal layer using a conductive paste containing carbon nanotubes, where FIGS. 2 and 3 represent corresponding processes.

The carbon nanotubes may be mono-wall types or multi-wail types. The conductive paste may include not only the carbon nanotubes but also metal particles, binders, and curing agents. The metal particles may be silver nanoparticles.

The first metal layer 11 may be a thin copper foil. The bumps, as shown in FIG. 3, can be formed by positioning a mask having through-holes over the first metal layer 11, and then filling the conductive paste into the through-holes using a squeegee. The bumps 12 may then undergo a curing process. The temperature for the curing process may be 180 to 200° C. If the temperature of the curing process is higher than 200° C., peeling between layers may occur, whereby the board may be bent. Moreover, if the temperature of the curing process is higher than 350° C., the binders of the bump 12 can be incinerated.

Operation S12 of FIG. 1 may be to stack an insulation layer on the first metal layer such that the bumps penetrate the insulation layer, where FIG. 4 represents a corresponding process. The insulation layer 13 may contain resin and glass fibers. The bumps 12 can be made to penetrate through the insulation layer 13 by the stacking process, as illustrated in FIG. 4.

Operation S13 of FIG. 1 may be to stack a second metal layer on the insulation layer such that the second metal layer is electrically connected with the first metal layer by the bump, where FIG. 5 represent a corresponding process.

The second metal layer 14 may be of the same material as that of the first metal layer 11. The second metal layer 14 can be stacked on the insulation layer 13 by pressing under high-temperature and high-pressure conditions, after which the first metal layer 11 can be electrically connected with the second metal layer 14 by the bumps 12.

Operation S14 of FIG. 1 may be to remove portions of the first and second metal layers to form at least one circuit pattern, where FIG. 6 represent a corresponding process.

As shown in FIG. 6, the circuit pattern 15 can be formed by removing portions of the first and second metal layers 11, 14 using a subtractive process. Areas of the circuit pattern 15 can be positioned over the bumps 12, whereby the circuit patterns 15 above and below the insulation layer 13 may be connected.

Looking at the magnified view in FIG. 6, a bump 15 may contain metal particles 16, with the carbon nanotubes 17 included among the metal particles 16. The carbon nanotubes 17 may serve to lower specific resistance by shortening the path of electric currents flowing through the metal particles 16.

Carbon nanotubes 17 provide superb electrical properties, as shown in the following Table 1.

TABLE 1
Properties of Carbon Nanotubes

| Physical Property | Carbon Nanotubes | Comparative Materials |
|---|---|---|
| Density | 1.33~1.40 g/cm³ | 2.7 g/cm³ (Aluminum) |
| Current Density | 1 × 10⁹ A/cm² | 1 × 10⁶ A/cm² |
| | | (Copper Cable) |
| Thermal Conductivity | 6000 W/mk | 400 W/mk (Copper) |
| Specific Resistance | 1 × 10⁻¹⁰ Ω · cm | 1 × 10⁻¹⁰ Ω · cm (Copper) |

As show in Table 1, carbon nanotubes have superb electrical properties compared to copper and aluminum. Therefore, the carbon nanotubes may decrease electrical resistance when used for interconnecting layers. Moreover, the carbon nanotubes also provide good thermal conductivity, so that heat inside a printed circuit board can be spread out easily.

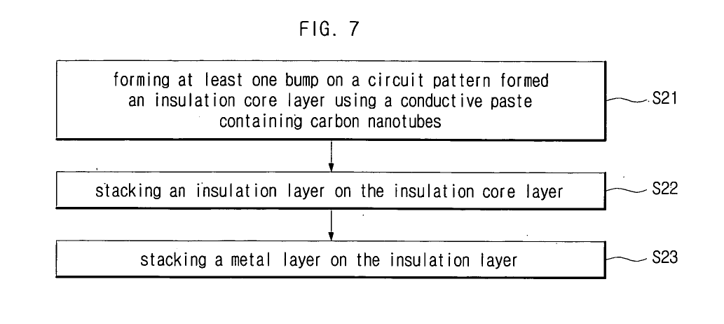

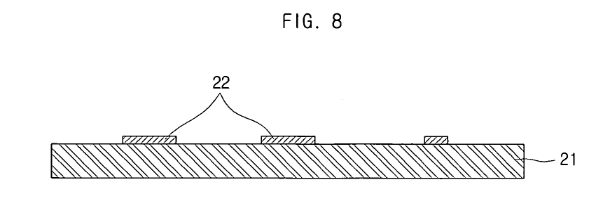

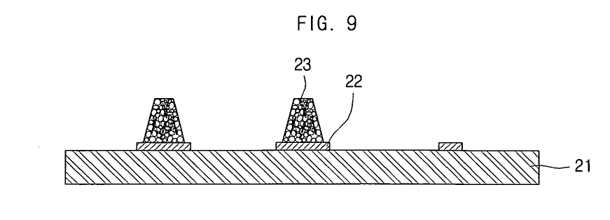

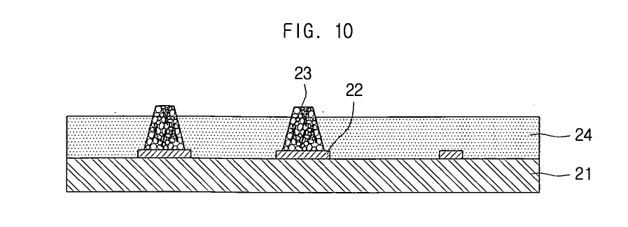

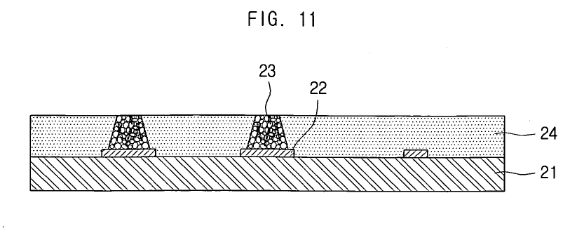

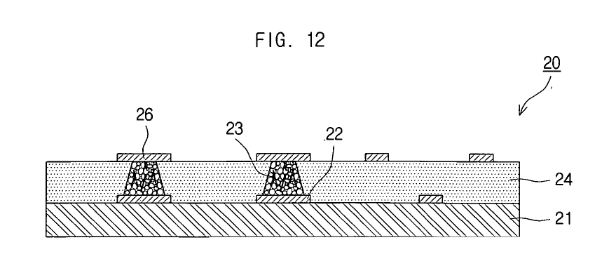

FIG. 7 is a flowchart for a method of interconnecting layers of a printed circuit board according to a second disclosed embodiment of the invention, and FIG. 8 to FIG. 12 are cross-sectional views representing processes for a method of interconnecting layers of a printed circuit board according to a second disclosed embodiment of the invention. In FIGS. 8 to 12 are illustrated a printed circuit board 20, an insulation core layer 21, circuit patterns 22, 26, bumps 23, and an insulation layer 24.

Operation S21 of FIG. 7 may be to form at least one bump on a circuit pattern formed an insulation core layer using a conductive paste containing carbon nanotubes. FIGS. 8 and 9 represent corresponding processes.

In this embodiment, a member may be prepared in which the circuit pattern 22 is already formed on the insulation core layer 21. The insulation core layer 21 may be a general insulating material such as prepreg. The bumps 23 may be formed on portions of the circuit pattern 22. The bumps 23 may be formed from a conductive paste containing carbon nanotubes. The method of forming the bumps 23 and the composition of the conductive paste can be substantially the same as already explained above regarding the previously disclosed embodiment.

Operation S22 of FIG. 7 may be to stack the insulation layer on the insulation core layer, where FIG. 10 represents a corresponding process.

The insulation layer 24 may be contain resin and glass fibers. The bumps 23 can be made to penetrate through the insulation layer 24 by a stacking process.

Operation S23 of FIG. 7 may be to stack a metal layer on the insulation core layer, and operation S24 may be to form a circuit pattern by removing portions of the metal layer, where FIGS. 11 and 12 represent corresponding processes. The metal layer may be stacked on the insulation layer 24 by pressing under high-temperature and high-pressure conditions. The metal layer can be a thin copper foil.

Afterwards, the circuit pattern 26 can be formed by removing portions of the metal layer. The circuit patterns 22, 26 above and below the insulation layer 24 can be interconnected by bumps 23.

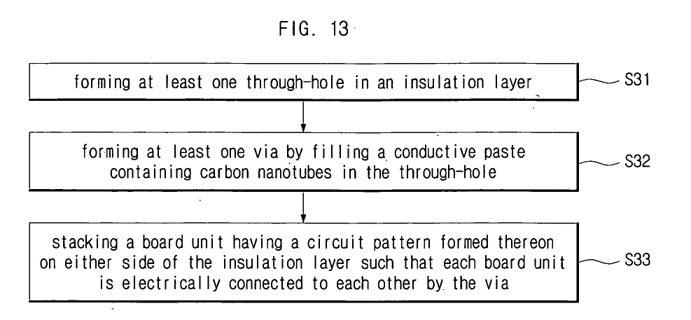

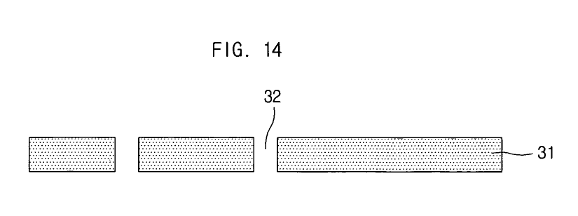

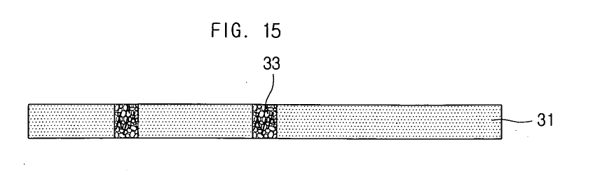

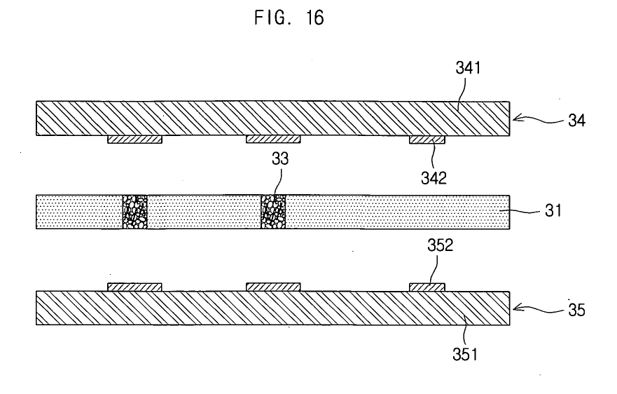

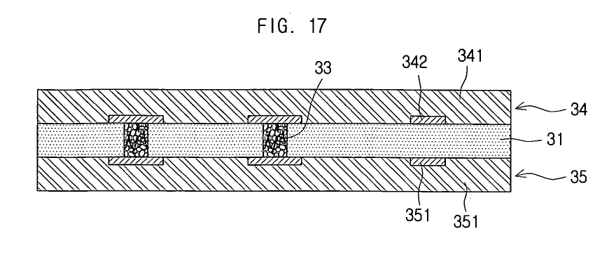

FIG. 13 is a flowchart for a method of interconnecting layers of a printed circuit board according to a third disclosed embodiment of the invention, and FIG. 14 to FIG. 17 are cross-sectional views representing processes for a method of interconnecting layers of a printed circuit board according to a third disclosed embodiment of the invention. In FIGS. 14 to 17 are illustrated an insulation layer 31, through-holes 32, vias 33, board units 34, 35, insulation layers 341, 351, and circuit patterns 342, 352.

Operation S31 of FIG. 13 may be to form through-holes in an insulation layer, where FIG. 14 represents a corresponding process. The insulation layer 31 may contain resin and glass fibers. The through-holes 32 can be formed by drilling through the insulation layer 31.

Operation S32 of FIG. 13 may be to form vias by filling a conductive paste containing carbon nanotubes, where FIG. 15 represents a corresponding process. The conductive paste may have not only carbon nanotubes but also metal particles, binders, and curing agents. The metal particles may be silver nanoparticles.

The vias 33 can be formed by filling the through-holes 32 using a squeegee or any other similar instrument. The vias 33 may serve as conduction paths that interconnect different layers.

Operation S33 of FIG. 13 may be to stack a board unit having a circuit pattern formed thereon onto either side of the insulation layer, such that each board unit is electrically connected to each other by the vias. FIGS. 16 and 17 represent corresponding processes.

The board units 34, 35 can include circuit patterns formed on insulation layers 341, 351. As shown in FIG. 16, those board units 34, 35 may each be aligned at one side of the insulation layer 31, and then the printed circuit board 30 can be formed by a lay-up process. A lay-up process may be performed by collectively pressing the aligned layers. Here, the vias 33 may interconnect the board units 34, 35. Therefore, portions of the circuit patterns may have to be exposed in correspondence with to the vias 33.

As set forth above, certain embodiments of the invention can provide a method of interconnecting layers of a printed circuit board using a conductive paste containing carbon nanotubes as bumps to interconnect the circuit layers of the printed circuit board.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of interconnecting layers of a printed circuit board, the method comprising:
forming at least one bump on a first metal layer using a conductive paste containing carbon nanotubes;
stacking an insulation layer on the first metal layer such that the bumps penetrate the insulation layer; and
stacking a second metal layer on the insulation layer such that the second metal layer is electrically connected with the first metal layer by the bump.

2. The interconnecting method of claim 1, wherein the conductive paste further contains metal particles and binders.

3. The interconnecting method of claim 1, wherein the first metal layer is a circuit pattern formed on a surface of an insulation core layer.

4. The interconnecting method of claim 1, further comprising, after stacking the second metal layer:
removing portions of the first and second metal layers to form at least one circuit pattern.

5. A method of interconnecting layers of a printed circuit board, the method comprising:
forming at least one through-hole in an insulation layer;
forming at least one via by filling a conductive paste containing carbon nanotubes in the through-hole; and
stacking a board unit having a circuit pattern formed thereon on either side of the insulation layer such that each board unit is electrically connected to each other by the via.

6. The interconnecting method of claim 5, wherein the conductive paste further contains metal particles and binders.
